(19) United States
(12) Patent Application Publication
(10) Pub. No.: US 2008/0303092 A1
(43) Pub. Date: Dec. 11, 2008

(54) Asymetrical Field-Effect Semiconductor Device with Sti Region

(75) Inventor: Theodore James Letavic, Putnam Valley, NY (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/158,105

(22) PCT Filed: Dec. 11, 2006
(86) PCT No.: PCT/IB06/54749

§ 371 Date: Jun. 19, 2008

Related U.S. Application Data
(60) Provisional application No. 60/751,531, filed on Dec. 19, 2005.

(51) Int. Cl. H01L 29/00; H01L 21/336

(52) U.S. Cl. 257/355; 438/286; 257/E21.409; 257/E29.001

(57) ABSTRACT

A high voltage asymmetric semiconductor device (20) that includes a shallow trench isolation (STI) region (22) that forms a dielectric between a drain (34) and a gate (36) to allow for high voltage operation, wherein the STI region includes a lower corner (24) that is shaped, e.g. rounded, to reduce an impact ionization rate. Exemplarity the shaped corner terminates on a (111) crystalline plane facet.

The invention relates generally to semiconductor device structures, and more particularly, to a semiconductor device structure having a shallow trench isolation (STI) region that forms a dielectric between the drain and the gate in which a bottom corner of the STI region is rounded.

Asymmetric semiconductor devices contain a shallow trench isolation (STI) region inside the unit cell, and all on-state current must flow beneath the STI bottom corner to exit the surface drain. STI regions are generally formed in a trench defined by two corners of approximately 90 degrees. Unfortunately, because the current must flow beneath the trench, the sharp corners result in high electric fields, which reduce the robustness of the device. Accordingly, a need exists for an asymmetric semiconductor device that includes an optimally shaped STI region.

The present invention addresses the above-mentioned problems, as well as others, by providing an asymmetric semiconductor device in which the STI region is optimally shaped to improve device reliability by reducing the impact ionization rate. In a first aspect, the invention provides an asymmetric semiconductor device that includes a shallow trench isolation (STI) region that forms a dielectric between a drain and a gate to allow for high voltage operation, wherein the STI region includes a lower corner that is shaped to reduce an impact ionization rate.

In a second aspect, the invention provides a method of forming an asymmetric semiconductor device, comprising: forming a deep well implant of a first type; forming a first well implant of the first type above the deep well implant and below a drain location and part of a gate location; and forming a shallow trench isolation (STI) region in the first well implant below a portion of the gate location adjacent the drain location, wherein the STI region includes a lower corner that is shaped to reduce an impact ionization rate.

In a third aspect, the invention provides an asymmetric semiconductor device that includes a shallow trench isolation (STI) region that forms a dielectric between two active regions, wherein the STI region includes a lower corner that is shaped to improve device performance.

These and other features of this invention will be more readily understood from the following detailed description of the various aspects of the invention taken in conjunction with the accompanying drawings in which:

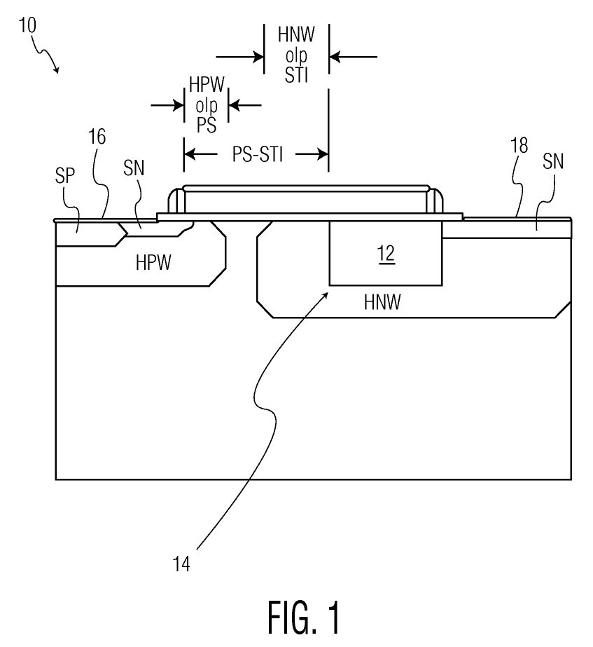

FIG. 1 depicts a cross-sectional layout of an asymmetric high voltage device integrated into a dense 0.25 um CMOS process having a Shallow Trench Isolation (STI) region with conventional STI trench bottom corners.

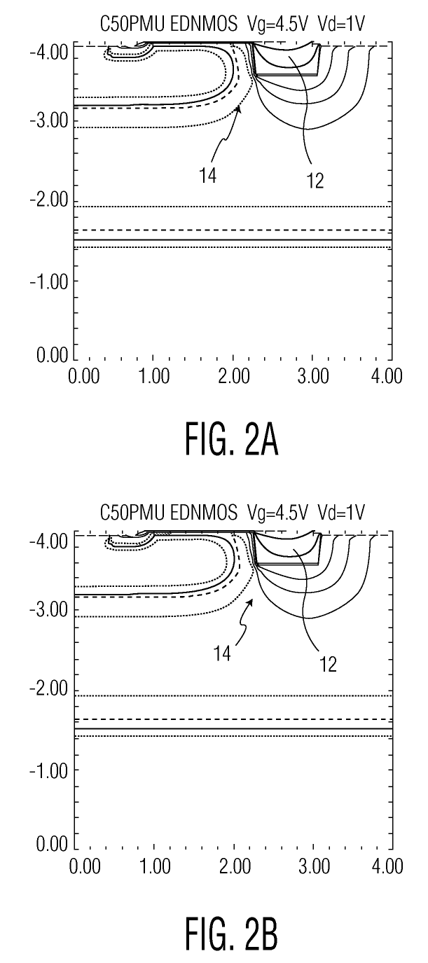

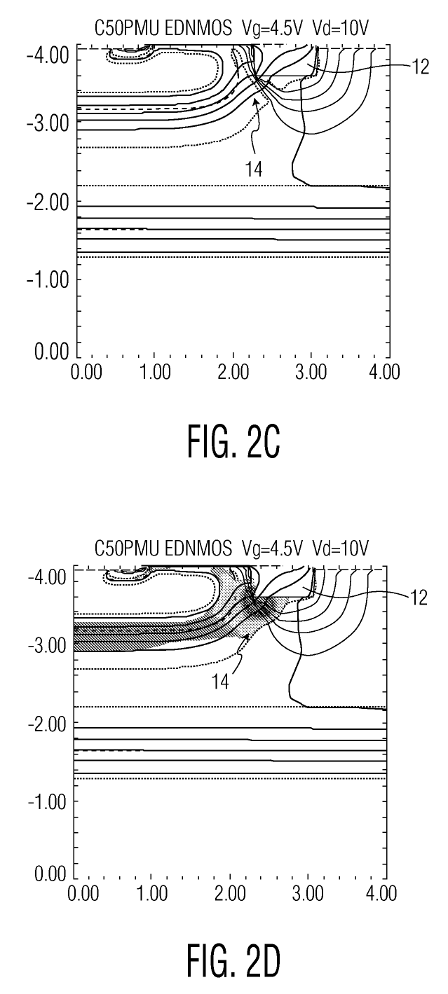

FIG. 2 depicts simulations of impact ionization as a function of drain bias for the device of FIG. 1.

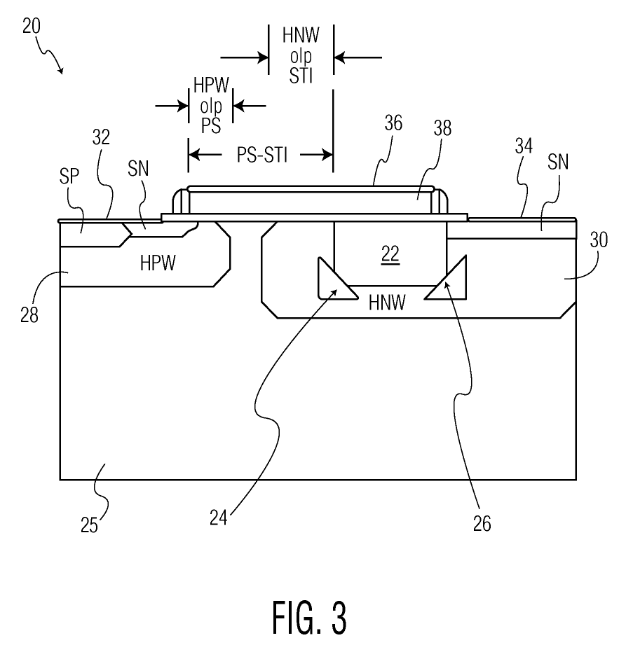

FIG. 3 depicts a cross-sectional layout of an asymmetric high voltage device that includes rounded STI trench corners in accordance with the present invention.

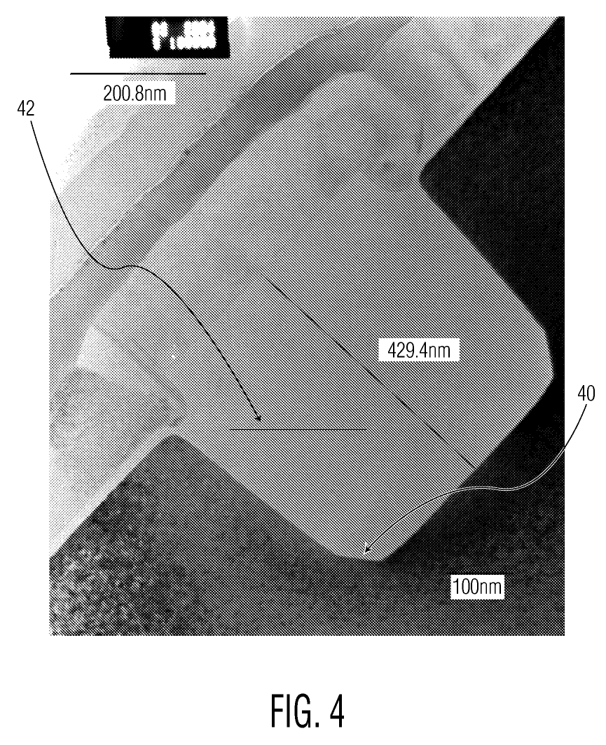

FIG. 4 depicts a TEM of an STI region having rounded corners in accordance with the present invention.

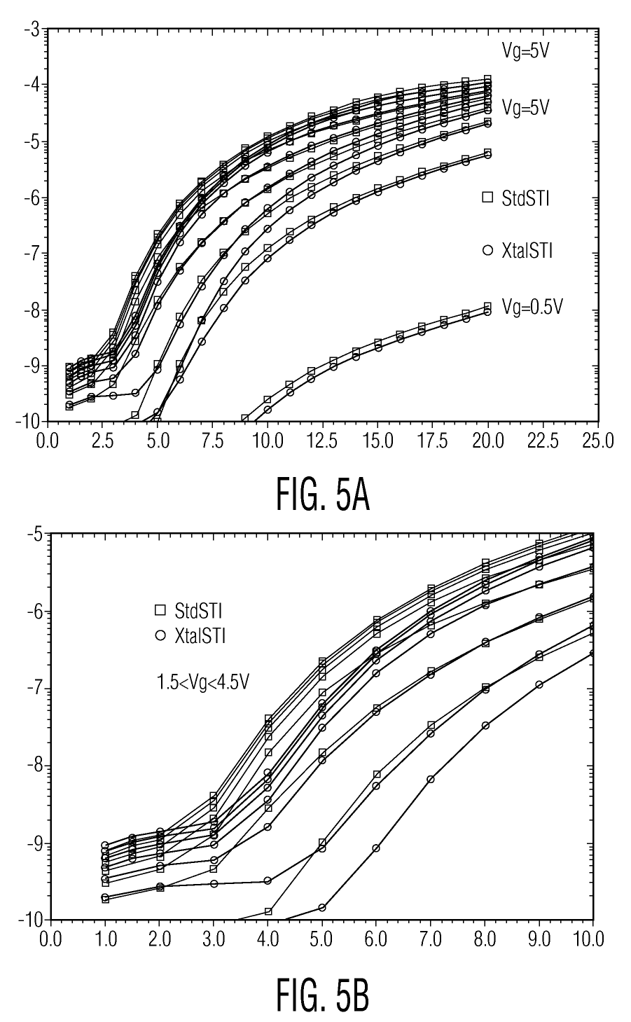

FIG. 5 depicts body current simulations for standard and trench corner rounded asymmetric device structures.

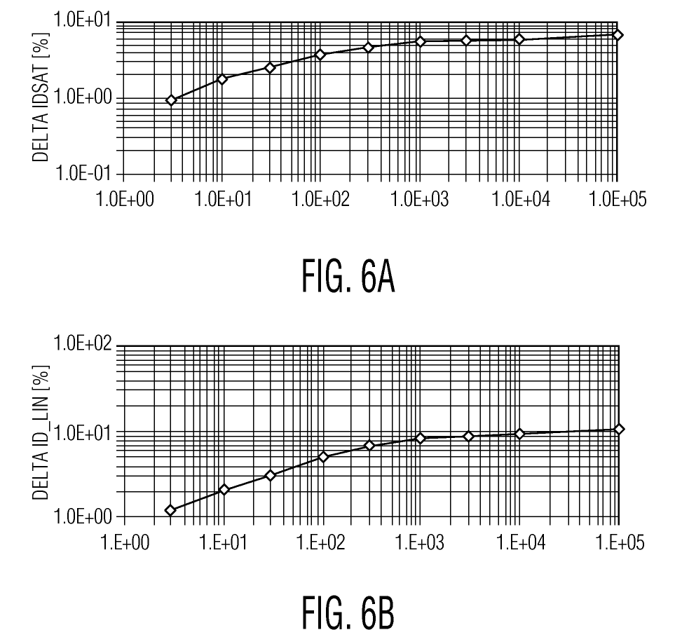

FIG. 6 depicts measured current degradation for devices with a faceted bottom trench corner.

The present invention provides an optimal shape for a Shallow Trench Isolation (STI) trench used in an asymmetric high voltage device. FIG. 1 depicts a cross-sectional view of an asymmetric high voltage 20V device structure 10 integrated into a dense 0.25 μm CMOS in which the STI 12 (without optimal shaping) is placed inside the device unit cell between the source 16 and drain 18 to form a dielectric to allow for high voltage operation. In the on-state, all current must spread from the channel region under the STI 12 to exit the surface drain 18. A high electric field at the bottom STI trench corner 14 plus the existence of channel current results in a high value of E*J, hence a high impact ionization rate.

From a surface perspective, device structure 10 may typically be fabricated in a ring-like fashion (not shown) such that STI 12 forms a ring around drain 18 and source 16 forms a ring around STI 12. Accordingly, a first active region (e.g., drain 18) comprises a center finger or stripe that is surrounded on all sides by a non-active region (i.e., STI 12), which is then surrounded on all sides by a second active region (e.g., source 16).

FIG. 2 shows simulated electric field, current flow, and impact ionization for a standard STI module flow (e.g., for the cross-section of the device in FIG. 1) in which the bottom trench corner is 88 degrees with respect to the surface plane. This sequence of simulations as a function of drain voltage in the on-state clearly shows the problem with impact ionization at the bottom trench corner 14. Hot carriers from this multiplication result in degradation of the on-state parameters of threshold voltage, linear current, and saturated current over the life of the device. As described below, the present invention provides an optimal shape of the STI region in order to increase reliability.

FIG. 3 depicts a cross-section of an asymmetric 20V device structure 20, similar to that shown in FIG. 1, in which the STI 22 is optimally shaped to improve device reliability by reducing the impact ionization rate. As can be seen, bottom corners 24 and 26 have been “rounded” in order to eliminate the sharp corners. In this illustrative embodiment, corners 24 and 26 have been terminated on a <111> crystalline facet plane, reducing the electric field enhancement previously caused by the sharp bottom STI corner 14 (FIG. 1). This shaping of the corners 24, 26 provides a factor of 8-10 reduction in body or impact ionized current in the ohmic bias region, giving at least a factor-of-four improvement in hot-carrier reliability. An insight of this invention is that the bottom trench corner geometry almost completely determines the robustness of the device structure 20 to hot carrier injection, as the nature of a lateral asymmetric device is that all source current must flow directly beneath the trench bottom corner 24 to exit the surface drain 34 of the device 20. Experimental results indicate that bottom corner trench termination on a crystalline facet plane can achieve general quality standards for current degradation over the lifetime of the device.

The illustrative device 20 shown in FIG. 3 provides an extended drain nchannel device (EDNMOS) which is formed using STI 22 within the unit cell of the device structure. The device 20 includes a DNWell (deep n-well implant) layer 25, an HPW (high voltage p-well implant) layer 28 beneath the source 32, and an HNW (high voltage n-well implant) layer 30 beneath the drain 34 and a portion of the gate 36. In this case, the STI 22 sits within the HNW layer 30 and forms a thick dielectric region between the drain 34 and source 32, which allows the device 20 to support voltages much higher than that which the baseline CMOS process flow is designed for.

An extended drain pchannel device could be implemented simply by reversing the wells, i.e., using the low-voltage PMOS process modules to form the extended drain PMOS (EDPMOS).

High voltage (>10V) asymmetric devices, such as that shown in FIG. 3, are fabricated in a 0.25 um CMOS process flow by adding the STI 22 between the drain 34 and source 32 in the unit cell. The polysilicon gate region 38 extends over the STI 22, allowing the thick STI dielectric to support drain-gate voltage. This breaks the standard scaling rule of gate oxide thickness to application voltage. A first bottom corner 24 of the STI is terminated on a <111> facet, reducing the electric field enhancement that previously would occur due to the sharp bottom STI corner. The second bottom corner 26 may also be terminated using a same/similar facet. Note that for the purpose of this disclosure, the terms “rounded” and “rounding” refer to any shaping that eliminates the sharp (˜90 degree) corner typically found in an STI.

While top trench corner rounding is known to be used in CMOS process flows to improve the gate oxide integrity, providing an optimal shape of the bottom trench corners for lateral asymmetric high voltage devices has not been previously utilized.

FIG. 4 depicts a TEM (transmission electron microscopy) of an optimized trench geometry for asymmetric power devices. The bottom trench corner 40 is terminated on a <111> plane facet, resulting in a “rounded” bottom corner 40. This relieves the electric field at any given drain bias at the bottom corner 40, which will improve device reliability by reducing the impact ionization rate. The crystalline texture of this facet is slightly altered by thermal oxidation. The horizontal line 42 in the trench dielectric represents the orientation of a <111> plane facet.

A series of on-state simulations were performed to determine the effect of bottom STI corner rounding on impact ionization current flow. A good metric for the effect of multiplication in a MOS semiconductor device is the measurement of body current as a function of applied bias. Simulation of body current as a function of bias is shown in FIG. 5, in which the lines with squares simulate a standard trench, and lines with circles simulate a trench corner with rounded design. The y-axis represents log Iii in Amps/μm and the x-axis represents drain voltage of an EDNMOS C50 power management unit. In each case, a reduction in the body currents in the ohmic region of conduction of a factor-of-eight is observed. Using a well known empirical relationship of body current to total on-state current, this would provide a factor-of-three improvement in effective device lifetime under hot carrier stress.

Standard hot carrier injection lifetime tests were performed on extended drain NMOS devices with layout of FIG. 3 (using the trench geometry of FIG. 4). Devices were biased in both the linear and the saturated current flow regime, the worst-case scenario for generation of impact ionized current at the bottom trench corner of the device. FIG. 6 shows the lifetime degradation characteristics linear current (Idlin) and saturated current (Idsat) for extended drain devices with faceted bottom trench corner geometry (Log[dI] vs Log[time]).

FIG. 6 confirms that the linear bias region is the worst case for hot carrier generation due to impact ionization J*E, and that the total parametric shift in current is less than 10% over life. This meets general quality specification for a 10 year life, and is at least a factor of three improvement over a 90 degree bottom trench corner.

The device 20 shown in FIG. 3 may be constructing according to any methodology. For instance it may be fabricated by: forming a deep well implant 25 of a first type (e.g., DNWell); forming a first well implant 30 of the first type (HNW) above the deep well implant and below a drain location 34 and part of a gate location 36; and forming a shallow trench isolation (STI) region 22 in the first well implant 30 below a portion of the gate location 36 adjacent the drain location 34, wherein the STI region 22 includes a lower corner 24 that is shaped to reduce an impact ionization rate. Shaping of the lower corner 24 may be done in any now known or later developed manner, and any type of shaping that improves device performance falls within the intended scope of this invention.

The foregoing description of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims.

1. An asymmetric semiconductor device that includes a shallow trench isolation (STI) region that forms a dielectric between a drain and a gate to allow for high voltage operation, wherein the STI region includes a lower corner that is shaped to reduce an impact ionization rate.

2. The device of claim 1, wherein the lower corner is rounded.

3. The device of claims 1, wherein the lower corner comprises a crystalline facet.

4. The device of claims 1, further comprising:
a substrate comprising a deep well implant of a first type patterned above an epitaxial layer;
a first well implant of the first type surrounding the STI region; and a second well implant of a second type residing below a source.

5. The device of claim 4, further comprising a polysilicon wall that reside above the STI region and extends towards the source.

6. The device of claim 1, wherein a second lower corner of the STI region is rounded.

7. A method of forming an asymmetric semiconductor device, comprising:
forming a deep well implant of a first type;
forming a first well implant of the first type above the deep well implant and below a drain location and part of a gate location; and
forming a shallow trench isolation (STI) region in the first well implant below a portion of the gate location adjacent the drain location, wherein the STI region includes a lower corner that is shaped to reduce an impact ionization rate.

8. The method of claim 7, wherein the lower corner is rounded.

9. The method of claims 7, wherein the lower corner is formed with a crystalline facet.

10. The method of claims 7, further comprising: forming a second well implant of a second type below a source location.

11. The method of claim 10, further comprising forming a polysilicon wall above the STI region that extends towards the source location.

12. The method of any preceding claim, comprising the further step of shaping a second lower corner of the STI region.

13. An asymmetric semiconductor device that includes a shallow trench isolation (STI) region that forms a dielectric between two active regions, wherein the STI region includes a lower corner that is shaped to improve device performance.

14. The device of claim 13, wherein the lower corner is rounded.

15. The device of claims 13, wherein the lower corner comprises a crystalline facet.

16. The device of claims 13, further comprising:
a substrate comprising a deep well implant of a first type patterned above an epitaxial layer;
a first well implant of the first type surrounding the STI region; and
a second well implant of a second type residing below a source.

17. The device of claim 16, further comprising a polysilicon wall that reside above the STI region and extends towards the source.

18. The device of claim 13, wherein a second lower corner of the STI region is rounded.
